(19) United States
(12) Patent Application Publication
(10) Pub. No.: US 2026/0237591 A1
(43) Pub. Date: Aug. 13, 2026

(54) MULTIPOLE MAGNET ADJUSTMENT SYSTEM AND MULTIPOLE MAGNET ADJUSTMENT METHOD

(71) Applicants: KABUSHIKI KAISHA TOSHIBA, Kawasaki-shi (JP); TOSHIBA ENERGY SYSTEMS & SOLUTIONS CORPORATION, Kawasaki-shi (JP)

(72) Inventors: Takeshi TAKEUCHI, Yotsukaido Chiba (JP); Kazuyuki KAZAMA, Yokohama Kanagawa (JP)

(73) Assignees: KABUSHIKI KAISHA TOSHIBA, Kawasaki-shi (JP); TOSHIBA ENERGY SYSTEMS & SOLUTIONS CORPORATION, Kawasaki-shi (JP)

(21) Appl. No.: 19/566,564

(22) Filed: Mar. 13, 2026

Related U.S. Application Data
(63) Continuation of application No. PCT/JP2024/039550, filed on Nov. 7, 2024.

(30) Foreign Application Priority Data
Feb. 16, 2024 (JP) 2024-021826

(51) Int. Cl. H01J 37/147

(52) U.S. Cl. CPC H01J 37/147; H01J 2237/152

(57) ABSTRACT

According to one embodiment, a multipole magnet adjustment system includes: an X-axis drive motor moving a multipole magnet in an X-axis direction that is orthogonal to a traveling direction of the charged particle beam, the multipole magnet controlling a charged particle beam; a Y-axis drive motor moving the multipole magnet in a Y-axis direction that is orthogonal to the traveling direction and the X-axis direction; and a computer controlling the X-axis drive motor and the Y-axis drive motor, displaying a schematic image on a screen, the schematic image indicating a positional relationship between a vacuum duct and the multipole magnet surrounding the vacuum duct, the vacuum duct being a duct through which the charged particle beam passes, and moving a displayed position of the multipole magnet on the screen in response to movement of the multipole magnet caused by driving of the X-axis drive motor and the Y-axis drive motor.

### CROSS-REFERENCE TO RELATED APPLICATIONS

This application is a Continuation Application of No. PCT/JP2024/039550, filed on Nov. 7, 2024, and the PCT application is based upon and claims the benefit of priority from Japanese Patent Applications No. 2024-021826, filed on Feb. 16, 2024, the entire contents of which are incorporated herein by reference.

### TECHNICAL FIELD

Embodiments of the present invention relate to multipole magnet adjustment technology.

### BACKGROUND

A beam transport apparatus of a particle beam irradiation system is provided with a multipole magnet, such as a quadrupole magnet, for controlling a charged particle beam. The multipole magnet is disposed around an outer side of a vacuum duct through which the charged particle beam passes. When the multipole magnet is fixed, precise adjustment is required with reference to a passage position of the charged particle beam.

### PRIOR ART DOCUMENT

### Patent Document

[Patent Document 1] JP 2013-088126 A

[Patent Document 2] JP H01-162700 A

### SUMMARY

### Problem to be Solved by Invention

During position adjustment of the multipole magnet, if the multipole magnet collides with the vacuum duct, the entire beam transport apparatus is adversely affected, and additional time is required for the subsequent restoration and maintenance, with a risk of damage to equipment.

Conventionally, the position adjustment of the multipole magnet is performed in such a manner that an operator inputs a movement amount to a motor for moving the multipole magnet and visually checks the actual movement amounts of the multipole magnet and the vacuum duct to avoid a collision between the multipole magnet and the vacuum duct. When the position adjustment is performed by remote operation, the operator adjusts the position of the multipole magnet while previously grasping limit values of the movement amounts of the multipole magnet. In this case, due to the multipole nature of the multipole magnet, it is difficult to grasp limit values with respect to the X-axis and the Y-axis and a positional relationship, and thus, a collision between the multipole magnet and the vacuum duct cannot always be avoided. Accordingly, there is a demand for a system that enables the operator to readily and safely adjust the position of the multipole magnet while avoiding a collision between the multipole magnet and the vacuum duct.

In view of the above-described circumstances, embodiments of the present invention are provided for simultaneous achievement of both avoidance of a collision between the multipole magnet and the vacuum duct and easy and safe adjustment work by the operator during remote position adjustment of the multipole magnet by the operator.

### BRIEF DESCRIPTION OF DRAWINGS

FIG. 1 is a side view illustrating multipole magnets.

FIG. 2 is a front view illustrating one of the multipole magnets.

FIG. 3 is a side view illustrating a limit sensor apparatus.

FIG. 4 is a front view illustrating a light-shielding plate.

FIG. 5 is a block diagram illustrating a multipole magnet adjustment system.

FIG. 6 is a schematic diagram illustrating a screen display of a position-adjustment computer.

FIG. 7 is a schematic diagram illustrating a state of the multipole magnet before position adjustment.

FIG. 8 is a schematic diagram illustrating a state of the multipole magnet during position adjustment.

FIG. 9 is a schematic diagram illustrating a state of the multipole magnet after position adjustment.

FIG. 10 is a side view illustrating a limit sensor apparatus according to a first modification.

FIG. 11 is a side view illustrating a limit sensor apparatus according to a second modification.

FIG. 12 is a front view illustrating a light-shielding plate according to a third modification.

FIG. 13 is a front view illustrating a light-shielding plate according to a fourth modification.

FIG. 14 is a front view illustrating a light-shielding plate according to a fifth modification.

### DETAILED DESCRIPTION

A multipole magnet adjustment system according to embodiments of the present invention includes: an X-axis drive motor configured to move a multipole magnet in an X-axis direction that is orthogonal to a traveling direction of the charged particle beam, the multipole magnet being configured to control a charged particle beam; a Y-axis drive motor configured to move the multipole magnet in a Y-axis direction that is orthogonal to both the traveling direction and the X-axis direction; and a computer configured to control the X-axis drive motor and the Y-axis drive motor, display a schematic image on a screen, the schematic image indicating a positional relationship between a vacuum duct and the multipole magnet surrounding the vacuum duct, the vacuum duct being a duct through which the charged particle beam passes, and move a displayed position of the multipole magnet on the screen in response to movement of the multipole magnet caused by driving of the X-axis drive motor and the Y-axis drive motor.

According to embodiments of the present invention, an operator can perform adjustment work readily and safely during remote position adjustment of a multipole magnet while avoiding a collision between the multipole magnet and a vacuum duct.

Hereinbelow, embodiments of the present invention will be described in detail with reference to the accompanying drawing.

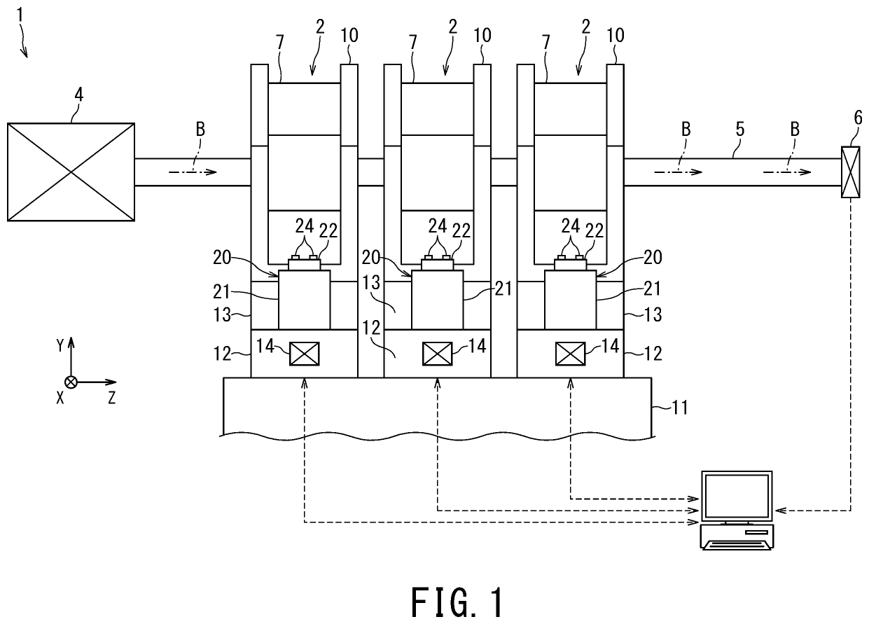

The reference numeral 1 in FIG. 1 denotes a multipole magnet adjustment system according to the present embodiment. The multipole magnet adjustment system 1 includes a limit detection system. The multipole magnet adjustment system 1 is used to perform a multipole magnet adjustment method and a limit detection method.

The multipole magnet adjustment system 1 is for performing fine position adjustment of each of a plurality of multipole magnets 2 when the multipole magnets 2 are disposed at predetermined locations. A user such as an operator of the multipole magnet adjustment system 1 can perform fine position adjustment of the multipole magnets 2 by operating a position-adjustment computer 3. The position-adjustment computer 3 includes a programmable logic controller (PLC) and its functions.

Each multipole magnet 2 is an apparatus for controlling the focusing and defocusing of a charged particle beam B. For example, the multipole magnet 2 is used in a beam transport apparatus (not shown) for transporting the charged particle beam B in a particle beam irradiation system (not shown). For example, a single vacuum duct 5 extending linearly from a predetermined beam generator 4 is provided. The vacuum duct 5 is a tubular member, interior of which is in a vacuum state. The vacuum duct 5 is fixed to a floor surface (not shown).

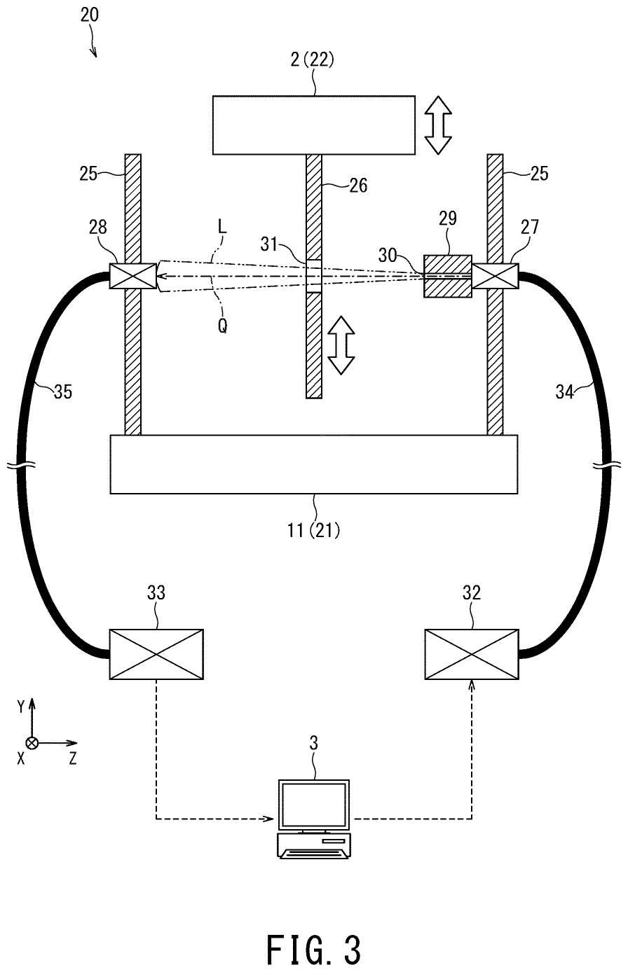

In FIGS. 1, 3, 10, and 11, the right side of the sheet is assumed to be the front side, i.e., the forward side, of each multipole magnet 2. The illustrated items are shown as specific cases. In particular, for FIGS. 3, 10, and 11, the same effects are achieved regardless of whether the front side is on the right side of the sheet or the left side of the sheet.

The charged particle beam B outputted from the beam generator 4 travels inside the vacuum duct 5 from the rear toward the front.

In the following description, the extending direction of the vacuum duct 5 and the traveling direction of the charged particle beam B are assumed to be the same and thus are together defined as the Z-axis direction, the vertical direction of the sheet is orthogonal to the Z-axis and is defined as the Y-axis direction, and the direction orthogonal to both the Z-axis and the Y-axis is defined as the X-axis direction.

As shown in FIG. 1, a beam detector 6 is mounted at the front end of the vacuum duct 5. The beam detector 6 is connected to the position-adjustment computer 3. The beam detector 6 is, for example, a Faraday cup. The beam detector 6 measures the beam current value of the charged particle beam B. The position of each multipole magnet 2 is finely adjusted in such a manner that this current value is maximized. The beam current value of the charged particle beam B is not necessarily maximized when the center of the selected one of the multipole magnets 2 is at the center of the vacuum duct 5. This is because the charged particle beam B does not necessarily pass through the center of the vacuum duct 5. For this reason, a user moves the multipole magnets 2 in the X-axis direction and the Y-axis direction to find the position at which the beam current value of the charged particle beam B is maximized.

For example, three multipole magnets 2 are provided along the vacuum duct 5 in the Z-axis direction. These multipole magnets 2 have the same configuration. Accordingly, the following descriptions relate to the position adjustment of a selected one of the multipole magnets 2 in the X-axis direction and the Y-axis direction. Although the selected multipole magnet may be different in Z-axis length, i.e., width dimension, from the other multipole magnets 2, the position adjustment in the X-axis direction and the Y-axis direction is generally performed in the same manner.

Each multipole magnet 2 is an electromagnet that generates a magnetic field for defining the trajectories of charged particles, i.e., ions, in the charged particle beam B traveling through the interior of the vacuum duct 5. The multipole magnets 2 are, for example, quadrupole magnets having four poles, i.e., N poles and S poles. The multipole magnets 2 may also be other types of electromagnets, such as dipole magnets, sextupole magnets, and octupole magnets.

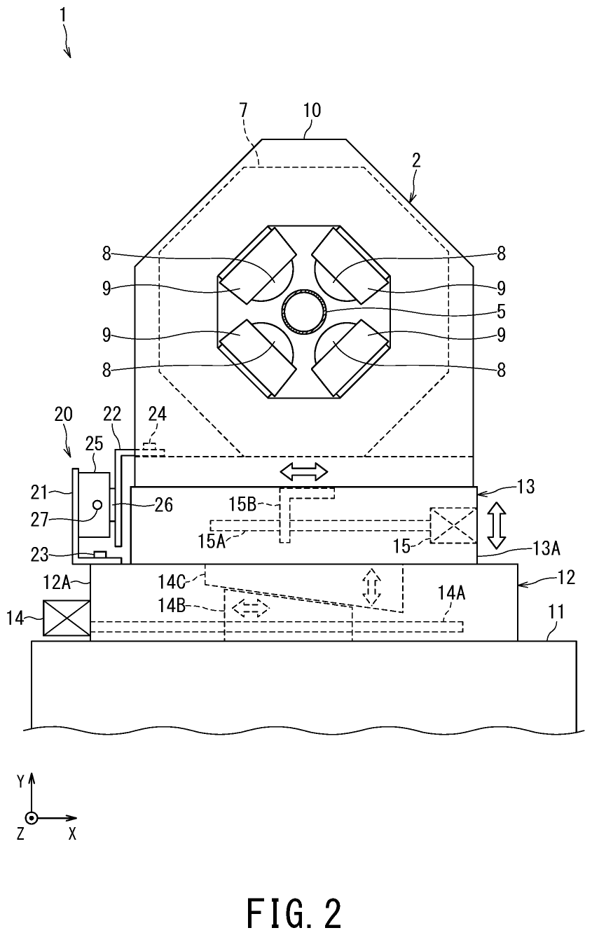

As shown in FIG. 2, each multipole magnet 2 includes a core body 7 that forms an octagonal shape when viewed from the front. The shape of the core body 7 is not necessarily limited to an octagonal shape. For example, the core body 7 may have a circular or square shape when viewed from the front.

The core body 7 has an opening formed at its center, and four core projections 8 protrude from the inner periphery of the opening. Coils 9 are wound around the respective core projections 8. The vacuum duct 5 extends in the front-rear direction, i.e., in the Z-axis direction, through the central opening of the core body 7.

The core projections 8 further protrude toward the vacuum duct 5. A predetermined gap is formed between the vacuum duct 5 and each core projection 8. The gap allows the multipole magnet 2 to be moved in the X-axis direction and the Y-axis direction and thereby enables fine position adjustment. If the multipole magnet 2 collides with or contacts the vacuum duct 5 during its position adjustment, additional time is required for the subsequent restoration and maintenance. Thus, it is necessary to prevent such a collision. The actual gap is 1 mm or less. A user adjusts the position of each multipole magnet 2 in increments of 0.1 mm or 0.2 mm, for example.

In a side view (see FIG. 1), each multipole magnet 2 is sandwiched in the front-rear direction, i.e., in the left-right direction in FIG. 1, by one U-shaped holding member 10. In other words, each multipole magnet 2 is disposed inside the corresponding holding member 10. The front surface and rear surface of each multipole magnet 2 are firmly fastened by fastening members such as bolts (not shown) while being in contact with the inner surface of the corresponding holding member 10.

On the floor surface (not shown) on which the multipole magnets 2 are disposed, a base 11 is fixed. On the upper surface of the base 11, lifting stages 12 for moving (i.e., raising or lowering) the respective multipole magnets 2 in the Y-axis direction are fixed. Each lifting stage 12 includes a Y-axis drive motor 14. Housings 12A of the respective lifting stages 12 are fixed to the base 11.

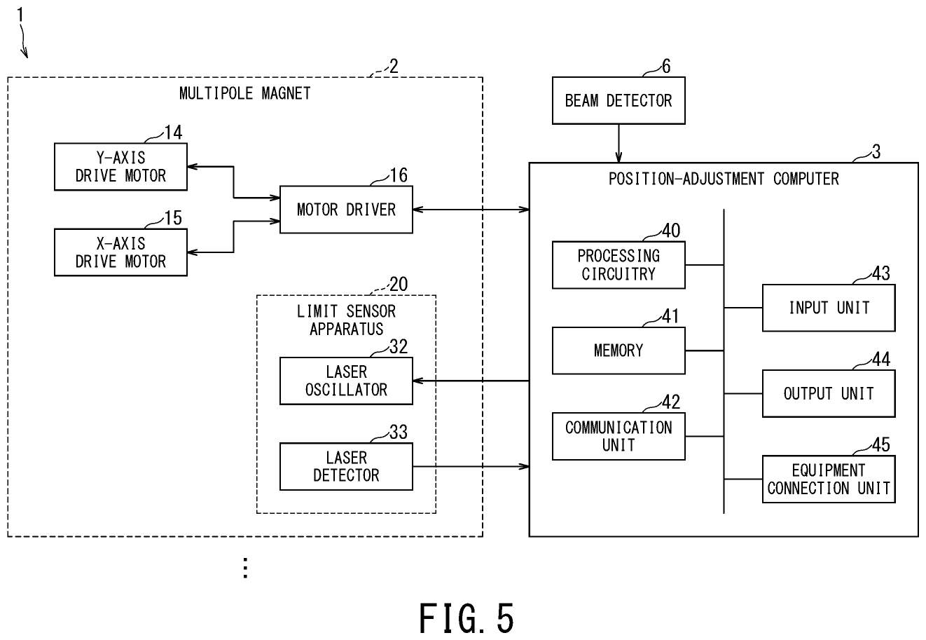

Above the respective lifting stages 12, lateral movement stages 13 for moving the multipole magnets 2 in the X-axis direction is provided. Each lateral movement stage 13 includes an X-axis drive motor 15. On the upper surface of a housing 13A of each lateral movement stage 13, the holding member 10 is fixed. The same number of pairs of the X-axis drive motor 15 and the Y-axis drive motor 14 as the number of the multipole magnets 2 are connected to the position-adjustment computer 3 via the same number of motor drivers 16 (see FIG. 5).

The vertical arrangement of the base 11, the lifting stages 12, and the lateral movement stages 13 is not limited to the vertical arrangement described in the present embodiment. For example, it may be configured in such a manner that the lateral movement stages 13 are mounted on the base 11 and the respective lifting stages 12 are mounted on the lateral movement stages 13.

Inside the housing 12A of each lifting stage 12, a Y-axis ball spline 14A connected to the Y-axis drive motor 14 is provided. A first wedge-shaped block 14B is provided to move in the X-axis direction in response to rotational driving of a respective one of Y-axis ball splines 14A. Each first wedge-shaped block 14B is a wedge-shaped member having an inclined upper surface. On the upper surface of each first wedge-shaped block 14B, a second wedge-shaped block 14C is provided. Each second wedge-shaped block 14C is a wedge-shaped member having an inclined lower surface.

When a selected one of the first wedge-shaped blocks 14B moves laterally, the corresponding second wedge-shaped block 14C is guided along the upper surface of the first wedge-shaped block 14B and thereby moves in the Y-axis direction. Each second wedge-shaped block 14C is fixed to a lower surface of the housing 13A of the corresponding lateral movement stage 13. Each lateral movement stage 13 moves vertically (i.e., is raised and lowered) together with the second wedge-shaped block 14C.

The housing 12a of each lifting stage 12 and the housing 13a of the lateral movement stage 13 corresponding to this lifting stage 12 are not coupled to each other and are movable relative to each other. The housing 12A of each lifting stage is an immobile member fixed to the base 11. The housing 13A of each lateral movement stage 13 is a member that moves in the vertical direction in response to driving of the corresponding lifting stage 12. That is, each lifting stage 12 serves as a stage for raising and lowering the corresponding lateral movement stage 13.

The X-axis drive motors 15 are provided inside the respective housings 13A of the lateral movement stages 13. An X-axis ball spline 15A connected to a respective one of the X-axis drive motors 15 is also provided. A bracket 15B configured to move in the X-axis direction as a lateral movement in response to rotational driving of a respective one of the X-axis ball splines 15A is also provided. Each bracket 15B is an L-shaped member and is fixed to the lower surface of the corresponding holding member 10. Each holding member 10 laterally moves together with the corresponding bracket 15B.

Each X-axis drive motor 15 moves the corresponding multipole magnet 2 in the X-axis direction, which is orthogonal to both the traveling direction of the charged particle beam B and the Y-axis direction. Each Y-axis drive motor 14 moves the corresponding multipole magnet 2 in the Y-axis direction, which is orthogonal to both the traveling direction of the charged particle beam B and the X-axis direction. These motors are configured as stepping motors. When power supply is stopped, the rotational position of the shaft of each motor is held fixed. For example, each of the X-axis drive motors 15 and the Y-axis drive motors 14 includes a permanent magnet, and the rotational position of the shaft is held by magnetic force of the permanent magnet. Accordingly, after adjustment of the multipole magnets 2, operation of the multipole magnets 2 is started with the X-axis drive motors 15 and the Y-axis drive motors 14 left in place.

The multipole magnet adjustment system 1 includes a limit sensor apparatus 20. During positioning of a selected one of the multipole magnets 2 with respect to the vacuum duct 5, the limit sensor apparatus 20 detects that this multipole magnet 2 has reached its limit position. With this configuration, a user such as an operator performing the adjustment operation can recognize that the multipole magnet 2 under adjustment has reached the limit position, and thus, a collision between the multipole magnet 2 and the vacuum duct 5 can be avoided. Each limit position is a position at which a collision between the multipole magnet 2 and the vacuum duct 5 occurs or is likely to occur, and is a position indicating a value that restricts movement of the multipole magnet 2, including an upper limit value and a lower limit value that define a limit of movement in the X-axis direction and a limit of movement in the Y-axis direction.

In the following description, the base 11 is exemplified as a first member, and each multipole magnet 2 is exemplified as a second member. The base 11 is fixed to the floor surface (not shown). Each multipole magnet 2 is movable with respect to the floor surface and the base 11. That is, the first member and the second member are two members that are movable relative to each other.

The limit sensor apparatus 20 includes: first jigs 21 fixed to the respective housings 12A of the lifting stages 12; and second jigs 22 fixed to the respective holding members 10. Each of the first and second jigs 21 and 22 is a plate member bent in an L-shape when viewed from the front. Each first jig 21 is fixed to the housing 12A of the corresponding lifting stage 12 by a fastening member such as a bolt 23. The housings 12A of the respective lifting stages 12 are fixed to the base 11. In other words, each first jig 21 is fixed to the base 11 serving as the first member via the housing 12A of the corresponding lifting stage 12. The second jigs 22 are fixed to the respective holding members 10 by fastening members such as bolts 24. In other words, each second jig 22 is fixed to the corresponding multipole magnet 2 serving as the second member via the holding member 10.

Two plate-shaped holding plates 25 (see FIG. 3) are fixed to a respective one of the first jigs 21. A single plate-shaped light-shielding plate 26 (see FIG. 3) is fixed to a respective one of the second jigs 22. In other words, each light-shielding plate 26 is fixed by the corresponding second jig 22 to the multipole magnet 2 serving as the second member, which is the other member different from the base 11 serving as the first member.

Although detailed illustrations are omitted, the holding plates 25 and the light-shielding plate 26 are plate-shaped, each having a bent portion. These bent portions is fixed to the first jig 21 and the second jig 22 by fastening members such as screws (not shown). Holes through which these screws are inserted are elongated holes (not shown) extending in the X-axis direction or in the Y-axis direction. The screws are disposed at predetermined positions within these elongated holes so that the mounting positions of the holding plates 25 and the light-shielding plate 26 in the X-axis direction and Y-axis direction can be finely adjusted.

The holes through which the bolts 23 and 24 for fixing the first and second jigs 21 and 22 to the lifting stage 12 and the holding member 10 are inserted may be elongated holes (not shown) extending in the X-axis direction or in the Y-axis direction. The bolts 23 and 24 may be disposed at predetermined positions within the elongated holes so that the mounting positions of the first and second jigs 21 and 22 in the X-axis direction and the Y-axis direction can be finely adjusted. In other words, enabling fine adjustment of the mounting positions of at least one of the holding plates 25, the light-shielding plate 26, and the first and second jigs 21 and 22 further enables adjustment of the relative mounting positions between the holding plates 25 and the light-shielding plate 26. The term “mounting position” refers to an arbitrary position in the X-axis direction and the Y-axis direction.

As shown in FIG. 3, the single light-shielding plate 26 is disposed between the two holding plates 25. The holding plates 25 and the light-shielding plate 26 are disposed in the front-rear direction, i.e., in the Z-axis direction, with a spacing therebetween. The holding plates 25 and the light-shielding plate 26 are disposed in such a manner that their front and rear surfaces face each other. In other words, the front and rear surfaces of the holding plates 25 and the light-shielding plate 26 extend in planes along the X-axis direction and the Y-axis direction.

The limit sensor apparatus 20 is a laser sensor that detects a limit position using a laser L. For example, the limit sensor apparatus 20 includes a light emitter 27 configured to emit the laser L and a light receiver 28 configured to receive the laser L. The limit sensor apparatus 20 is a transmissive laser sensor composed of the light emitter 27 and the light receiver 28.

The light emitter 27 is fixed to one of the holding plates 25. The light emitter 27 is provided with a light-intensity adjustment block 29 that prevents diffusion of the laser L. A through-hole 30, through which the laser L passes, is formed in the center of the light-intensity adjustment block 29. The through-hole 30 extends along the traveling direction of the laser L, i.e., in the Z-axis direction, and has a circular cross-section that defines the diameter of the laser L. The light-intensity adjustment block 29 may have a cylindrical or tubular shape.

The light receiver 28 is fixed to the other of the holding plates 25. In other words, the light receiver 28 is fixed by the first jig 21 to the base 11 serving as the first member, which is the same one member to which the light emitter 27 is fixed.

The light-shielding plate 26 (i.e., the light-blocking member) is disposed on the path of the laser L from the light emitter 27 to the light receiver 28. An opening 31, through which the laser L passes, is formed in the center of the light-shielding plate 26. It is configured in such a manner that the laser L emitted from the light emitter 27 passes through the opening 31 and reaches the light receiver 28. The laser L is emitted from the light emitter 27 toward the light receiver 28 at a predetermined and fixed intensity.

The light-shielding plate 26 moves in accordance with the movement of the corresponding multipole magnet 2. When the movement of the light-shielding plate 26 causes the passage position of the laser L to deviate from the opening 31 and thereby at least a portion of the laser L is blocked by the light-shielding plate 26, the amount of light to be received by the light receiver 28 decreases. The position-adjustment computer 3 acquires this amount of received light and determines whether the received light has decreased or not. In the case of the affirmative determination, the position-adjustment computer 3 can detect that the multipole magnet 2 has reached a limit position.

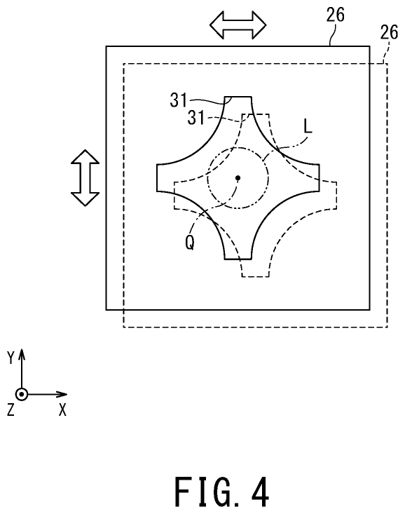

As shown in FIG. 4, the light-shielding plate 26 has a quadrilateral shape. The light-shielding plate 26 is cut out in such a manner that the shape of the opening 31 corresponds to the central opening of the multipole magnet 2. For example, the center of the light-shielding plate 26 is formed with an approximately cross-shaped opening, and four rounded or curved edges corresponding to the four core projections 8 are formed at its four corners (see FIG. 2). Each of the edges has a hyperbolic shape. The laser L spreads circularly about the optical axis Q. The diameter of the laser L is set to correspond to the diameter of the vacuum duct 5, and the size of the opening 31 is set in accordance with the diameter of the laser L.

The diameter of the laser L may be set larger to allow for a margin. For example, the size may be reduced to match the central opening of the multipole magnet 2, thereby forming the opening 31 in the light-shielding plate 26. The diameter of the laser L may be set slightly larger than in a case where the diameter of the vacuum duct 5 is reduced by the same reduction ratio under this condition. Adjustment of the positional relationship between the holding plates 25 and the light-shielding plate 26, for example, adjustment of the distance between them, can be used to adjust the ratio of the diameter of the laser L to the opening 31.

The range in which the laser L does not overlap the edges of the opening 31 of the light-shielding plate 26 corresponds to the movable range of the multipole magnet 2. This range represents the range in which the multipole magnet 2 does not collide with or contact the vacuum duct 5. In other words, the opening 31 of the light-shielding plate 26 is formed to have the same shape as the relative movement range between the base 11 serving as the first member and the multipole magnet 2 serving as the second member. The edges of this opening 31 define the limit positions of the movement range of the multipole magnet 2.

With this configuration, the shape of the opening 31 defines the movement range of the multipole magnet 2. The position-adjustment computer 3 can detect the limit positions on the basis of the shape of the opening 31. During movement of a selected one of the multipole magnets 2, the position-adjustment computer 3 stops the movement of the multipole magnet 2 at the time point at which the multipole magnet 2 reaches the limit position.

As shown in FIG. 3, the limit sensor apparatus 20 includes a laser oscillator 32 configured to emit the laser L and a laser detector 33 configured to detect the laser L. The laser oscillator 32 and the laser detector 33 are connected to the position-adjustment computer 3. Although the laser oscillator 32 and the laser detector 33 are illustrated as separate components to facilitate understanding, both may also be integrated as a single instrument.

The laser oscillator 32 is provided at a predetermined position different from the position of the light emitter 27 and is connected to the light emitter 27 via an emitting optical fiber 34. The laser detector 33 is provided at a predetermined position different from the position of the light receiver 28 and is connected to the light receiver 28 via a receiving optical fiber 35. The respective predetermined positions at which the laser oscillator 32 and the laser detector 33 are provided may be any locations as long as both are away from the base 11 and the multipole magnet 2.

The use of the emitting optical fiber 34 and the receiving optical fiber 35 allows the laser oscillator 32 and the laser detector 33 to be provided at positions different from the base 11 serving as the first member and the multipole magnet 2 serving as the second member. Accordingly, the base 11 and the multipole magnet 2 are not affected by the operation of the laser oscillator 32 and the laser detector 33. The use of the emitting optical fiber 34 and the receiving optical fiber 35 allows the components constituting the limit sensor apparatus 20 to avoid interfering with the movement of the multipole magnet 2.

The position-adjustment computer 3 acquires the amount of the laser L received by the light receiver 28. The position-adjustment computer 3 detects the difference between (i) the amount of received light when the laser L having passed through the opening 31 of the light-shielding plate 26 reaches the light receiver 28 and (ii) the amount of received light when the laser L partially blocked by the light-shielding plate 26 reaches the light receiver 28. When positioning the multipole magnets 2, on the basis of the detected difference, the position-adjustment computer 3 detects that the multipole magnet 2 has reached its limit position, i.e., detects the relative positional displacement between the base 11 serving as the first member and the multipole magnet 2 serving as the second member.

The laser L spreads circularly about the optical axis Q, and its optical power decreases as the distance from the optical axis Q increases. For example, the optical power is strongest at the optical axis Q, while the edges of the laser L are lower in optical power than the optical axis Q. The position-adjustment computer 3 may detect this variation in optical power, i.e., the difference in received optical power, and thereby detect the relative positional displacement between the base 11 serving as the first member and the multipole magnet 2 serving as the second member.

When the base 11 serving as the first member and the multipole magnet 2 serving as the second member are relatively displaced, the laser L emitted from the light emitter 27 is blocked by the light-shielding plate 26 and thereby the received optical power at the light receiver 28 is reduced, which facilitates detection of the relative positional displacement.

For example, the limit sensor apparatus 20 measures the received optical power when the laser L having passed through the opening 31 of the light-shielding plate 26 reaches the light receiver 28. This received optical power is set as a reference received optical power for determination. A received optical power attenuated by a predetermined amount from this reference received optical power is set as a threshold in advance.

When the multipole magnet 2 is moved and the received optical power reaches this threshold, it is determined that the relative positional displacement between the base 11 and the multipole magnet 2 has reached its limit. Since the received optical power also varies depending on the positional relationship between the holding plates 25 and the light-shielding plate 26 (e.g., the distance between them), the reference received optical power is set in accordance with these positional relationships.

The position-adjustment computer 3 acquires a change amount indicating the magnitude of the relative positional displacement on the basis of the difference in received optical power. With this configuration, the change amount indicating the magnitude of the relative positional displacement (i.e., the movement amount of the multipole magnet 2) can be determined from variations in received optical power.

Next, the system configuration of the multipole magnet adjustment system 1 will be described with reference to the block diagram shown in FIG. 5. The multipole magnet adjustment system 1 may include components other than the components shown in FIG. 5, and some of the components shown in FIG. 5 may be omitted.

The multipole magnet adjustment system 1 includes hardware resources such as a central processing unit (CPU), a graphics processing unit (GPU), a read only memory (ROM), a random access memory (RAM), a hard disk drive (HDD), and a solid state drive (SSD), and is constituted by the position-adjustment computer 3 in which information processing by software is implemented by executing various programs on a CPU using the hardware resources. The multipole magnet adjustment method and the limit detection method of the present embodiment are achieved by causing the position-adjustment computer 3 to execute various programs.

Each component of the multipole magnet adjustment system 1 does not necessarily need to be provided in a single computer. For example, the single multipole magnet adjustment system 1 may be achieved by a plurality of computers connected to each other via a network.

The position-adjustment computer 3 includes processing circuitry 40, a memory 41, a communication unit 42, an input unit 43, an output unit 44, and an equipment connection unit 45, for example.

The processing circuitry 40 is a circuit including a CPU, a GPU, or a dedicated or general-purpose processor, for example. The processor implements various functions by executing various programs stored in the memory 41. The processing circuitry 40 may also be constituted by hardware such as a field programmable gate array (FPGA) and an application specific integrated circuit (ASIC). The various functions can also be implemented by these hardware resources. The processing circuitry 40 may implement the various functions by combining hardware processing with software processing using the processor and programs.

The memory 41 stores predetermined programs to be executed by the processing circuitry 40. The memory 41 stores various information items required for executing the multipole magnet adjustment method and the limit detection method.

The communication unit 42 communicates with other computers via a predetermined communication line, such as a Local Area Network (LAN) and the Internet.

The input unit 43 receives predetermined information in accordance with operations performed by a user operating the position-adjustment computer 3. The input unit 43 includes input devices such as a mouse, a keyboard, and a touch panel. In other words, the position-adjustment computer 3 receives the predetermined information in response to operations performed on these input devices.

The output unit 44 outputs predetermined information. For example, the output unit 44 may be a display. The position-adjustment computer 3 includes a device for displaying images, such as a display configured to output an analysis result. The display may be separate from or integrated with the computer body. Additionally or alternatively, the predetermined information may be displayed on a display provided by another computer connected via a network.

Although the display is exemplified as the device for displaying images, other configurations may also be adopted. For example, images may be displayed using a touch-panel display, a head-mounted display, or a projector.

The equipment connection unit 45 is connected to predetermined external apparatuses and performs transmission and reception of information to/from the apparatuses. The equipment connection unit 45 is connected to the beam detector 6, the motor driver 16, the laser oscillator 32, and the laser detector 33.

The position-adjustment computer 3 controls the X-axis drive motors 15 and the Y-axis drive motors 14 via the motor drivers 16. Each motor driver 16 includes a nonvolatile memory. Each of the X-axis drive motors 15 and the Y-axis drive motors 14 includes an encoder configured to detect a drive amount. Each motor driver 16 can acquire and store the respective drive amounts of the corresponding X-axis drive motor 15 and the corresponding Y-axis drive motor 14 from their encoders. The drive amount corresponds to a movement amount of the corresponding multipole magnet 2.

The position-adjustment computer 3 sends a command signal including the drive amounts of the X-axis drive motor 15 and the Y-axis drive motor 14 to the corresponding motor driver 16. On the basis of the command signal, each motor driver 16 controls driving of the corresponding X-axis drive motor 15 and the corresponding Y-axis drive motor 14. After completing the driving, each motor driver 16 feeds back an actual drive amount to the position-adjustment computer 3. With this configuration, the position-adjustment computer 3 can recognize the actual position of each multipole magnet 2.

When the beam generator 4 outputs the charged particle beam B, radiation may be generated in the vicinity of the multipole magnets 2. Thus, the position-adjustment computer 3 is installed in a room different from the room where the multipole magnets 2 are disposed. A user remotely performs fine position adjustment of the multipole magnets 2 by using the position-adjustment computer 3.

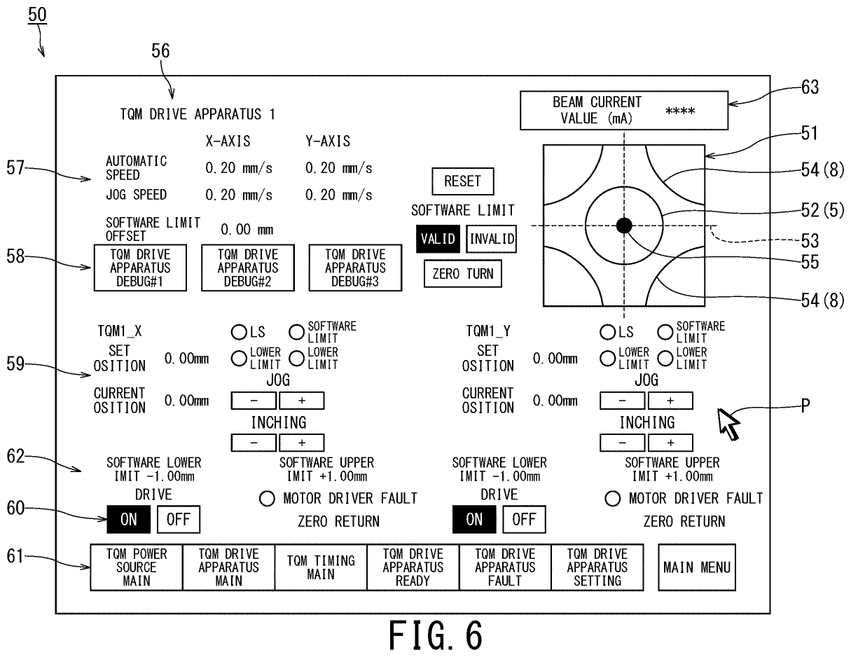

As shown in FIG. 6, the position-adjustment computer 3 causes a screen 50 to display a schematic image 51 indicating a positional relationship between the multipole magnet 2 surrounding the vacuum duct 5 and the vacuum duct 5 through which the charged particle beam B passes. The schematic image 51 is displayed on the screen 50 of a predetermined display serving as the output unit 44 (see FIG. 5). The position-adjustment computer 3 updates the displayed position of the multipole magnet 2 on the screen 50 in response to movement of the multipole magnet 2 resulting from driving of the corresponding X-axis drive motor 15 and the corresponding Y-axis drive motor 14.

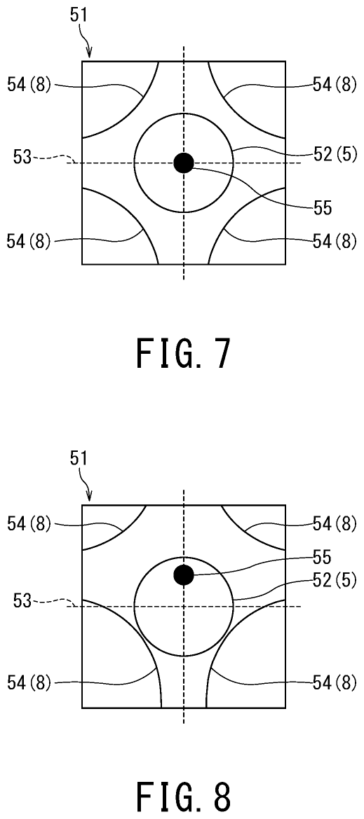

In the schematic image 51, a circular image 52, a reticle 53 (sighting lines), a pole image 54, and a center point 55 are depicted. The circular image 52 is an image in the form of a circle indicating the outer periphery of the vacuum duct 5 (see FIG. 2). The reticle 53 is an image indicating the center of the vacuum duct 5. The pole image 54 is an image of four corners, each indicating an edge of a respective one of the four core projections 8 (see FIG. 2), and each of these edges has a hyperbolic shape. The center point 55 is an image indicating the center of the four multipole magnets 2 (see FIG. 2). The center point 55 serves as the origin of the hyperbolic shapes of the core projections 8. Although the circular image 52 and the reticle 53 are fixedly displayed, the pole image 54 and the center point 55 change their displayed positions in response to movement of the multipole magnet 2 (see FIGS. 7 to 9).

FIG. 7 illustrates the schematic image 51 at an initial stage before position adjustment of the multipole magnets 2. First, when a user such as an operator disposes the multipole magnets 2 with respect to the vacuum duct 5, the user visually adjusts their relative positions so that the center of the vacuum duct 5 matches the center of the multipole magnets 2. This work is performed under the state where the beam generator 4 and the multipole magnets 2 are not operating. In this state, the respective positions of the holding plates 25 and the light-shielding plate 26 are also adjusted, and the optical axis Q of the laser L is made to coincide with the center of the opening 31 of the light-shielding plate 26. At this point, the schematic image 51 displayed on the screen 50 of the position-adjustment computer 3 is set in such a manner that the center of the reticle 53 coincides with the center point 55 of the multipole magnet 2. This state serves as the origin from which fine position adjustment of the multipole magnet 2 is performed.

Next, the user activates the beam generator 4 and the multipole magnets 2 and starts output of the charged particle beam B. The user then uses the screen 50 of the position-adjustment computer 3 to remotely perform fine position adjustment of the multipole magnets 2.

As shown in FIG. 8, when a selected one of the multipole magnets 2 is moved in the positive Y-axis direction (i.e., upward), the pole image 54 and the center point 55 indicating the position of the multipole magnet 2 move upward in the schematic image 51.

Similarly, when the multipole magnet 2 is moved in the negative Y-axis direction (i.e., downward), the pole image 54 and the center point 55 indicating the position of the multipole magnet 2 move downward in the schematic image 51.

Similarly, when the multipole magnet 2 is moved in the positive X-axis direction (i.e., to the right), the pole image 54 and the center point 55 indicating the position of the multipole magnet 2 move to the right in the schematic image 51.

Similarly, when the multipole magnet 2 is moved in the negative X-axis direction (i.e., to the left), the pole image 54 and the center point 55 indicating the position of the multipole magnet 2 move to the left in the schematic image 51.

As shown in FIG. 6, the screen 50 functions as a so-called graphical user interface (GUI) that allows a user to perform a predetermined selection input operation using a mouse pointer P. When the user clicks a given display with the mouse pointer P, a wizard for entering information (e.g., setting values) related to that display is presented. The user can use this wizard to enter any desired setting values.

On the screen 50, a name 56 identifying the multipole magnet 2 currently under adjustment among the three multipole magnets 2 is displayed, for example. A speed value 57 indicating the driving speed of each of the X-axis drive motor 15 and the Y-axis drive motor 14 is individually displayed. A magnet switching section 58 for switching the multipole magnet 2 to be adjusted among the three multipole magnets 2 is also displayed. A setting-value input section 59 for entering setting values of the X-axis drive motor 15 and the Y-axis drive motor 14 is displayed. The setting-value input section 59 displays the set position and the current position.

In addition to these items, the setting-value input section 59 displays values related to the limit sensor apparatus 20. For example, an LS lamp is displayed. When the multipole magnet 2 reaches its limit position, the LS lamp lights up. This allows the user to recognize that the multipole magnet 2 has reached the limit position.

A soft limit lamp is also displayed. The soft limit lamp lights up earlier than the LS lamp, with a margin taken in advance. For example, the soft limit lamp lights up immediately before the multipole magnet 2 reaches the limit position. This allows the user to manually stop movement of the multipole magnet 2 if desired.

An upper-limit lamp and a lower-limit lamp are also displayed. The upper-limit lamp lights up when the multipole magnet 2 reaches the limit position in the positive direction relative to the origin. The lower-limit lamp lights up when the multipole magnet 2 reaches the limit position in the negative direction relative to the origin.

The set position displayed in the setting-value input section 59 is a setting value entered by the user. In other words, the set position indicates the position to which the multipole magnet 2 is to be moved. The current position indicates the present position of the multipole magnet 2. The set position and the current position are displayed as numerical values in the X-axis direction or the Y-axis direction relative to the origin. In other words, the position-adjustment computer 3 displays numerical values representing the actual position (i.e., the current position) of the multipole magnet 2 together with the schematic image 51 on the single screen 50. This configuration allows the user to recognize the actual position of the multipole magnet 2 intuitively and instantly.

The user can control the X-axis drive motor 15 and the Y-axis drive motor 14 by entering arbitrary setting values in the setting-value input section 59. In other words, the position-adjustment computer 3 displays the setting values (i.e., set positions) of the drive amounts of the X-axis drive motor 15 and the Y-axis drive motor 14 together with the schematic image 51 on the single screen 50. This configuration allows the user to intuitively and instantly recognize the movement amount of the multipole magnet 2 on the basis of the respective drive amounts of the X-axis drive motor 15 and the Y-axis drive motor 14.

The user may operate the X-axis drive motor 15 and the Y-axis drive motor 14 by pressing and holding the JOG and the inching button instead of entering setting values. In this case, the current position based on the operation and the resulting movement is displayed on the screen 50. This configuration allows the user to readily recognize the movement amount of the multipole magnet 2 and the resulting current position.

The screen 50 displays a switch 60 for turning the main power of the X-axis drive motor 15 and the Y-axis drive motor 14 ON and OFF. An indication as to whether a fault has occurred in the motor driver 16 is also displayed. Furthermore, the screen 50 displays a function switching input section 61 for switching various functions.

The screen 50 displays restriction information 62 indicating an upper limit value and a lower limit value as limit values (i.e., limit positions) determined by the limit sensor apparatus 20. In other words, the position-adjustment computer 3 causes the single screen 50 to display the limit values (i.e., the restriction information 62) indicating the limit positions of the movement range of the multipole magnet 2 together with the schematic image 51. With this configuration, the user can readily grasp the limit values intuitively and instantly.

The central opening of the multipole magnet 2 (see FIG. 2) has an approximately cross-shaped configuration. Thus, when the center point 55 of the multipole magnet 2 is at the origin in the X-axis direction, the movable range in the Y-axis direction becomes large. However, as the center point 55 of the multipole magnet 2 moves away from the origin in the X-axis direction, the movable range in the Y-axis direction becomes smaller. In other words, the upper and lower limit values in the Y-axis direction vary depending on the position in the X-axis direction. Similarly, the upper and lower limit values in the X-axis direction vary depending on the position in the Y-axis direction.

The screen 50 further displays a beam current value 63 indicating the beam current value of the charged particle beam B measured by the beam detector 6. The user finely adjusts the position of a selected one of the multipole magnets 2 by moving it in the X-axis direction and in the Y-axis direction in such a manner that the beam current value 63 is maximized. In other words, the user searches for the position at which the beam current value 63 is maximized.

As described above, it is necessary to prevent the multipole magnet 2 from colliding with the vacuum duct 5. When the multipole magnet 2 approaches its limit position (i.e., the limit value), the position-adjustment computer 3 turns on the LS lamp as warning and stops the X-axis drive motor 15 and the Y-axis drive motor 14.

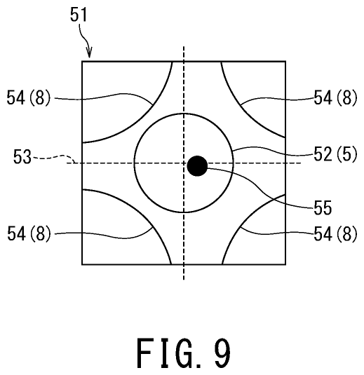

FIG. 9 illustrates the schematic image 51 in the state where the position adjustment of the multipole magnet 2 has been completed. The coincidence between the center of the reticle 53 and the center point 55 of the multipole magnet 2 in the schematic image 51 does not necessarily correspond to the state in which the beam current value 63 is maximized. For example, in the schematic image 51 as shown in FIG. 9, a state where the center point 55 of the multipole magnet 2 is offset from the center of the reticle 53 can be a state where the beam current value 63 is maximized.

At the time when the fine position adjustment of every multipole magnet 2 is completed, the limit sensor apparatus 20 is removed. The limit sensor apparatus 20 may remain attached without being removed.

A conventional photointerruptor-type limit sensor can only detect limit positions of a moving range of a member configured to move in a simple linear motion, and cannot detect limit positions of a moving range of another member configured to move in a planar (i.e., two-dimensional) direction. In contrast, in the limit sensor apparatus 20 (limit detection system) of the present embodiment, limit positions of a moving range can be set by the shape of the opening 31 of the light-shielding plate 26. Thus, the limit positions of the moving range of the member configured to move in the planar (i.e., two-dimensional) direction can be detected.

Next, first to fifth modifications will be described. In the following descriptions of the first to fifth modifications, the same reference numerals are assigned to components identical to those shown in the foregoing embodiments, and redundant descriptions are omitted. The configurations applied in at least one of the first to fifth modifications may be applied to the foregoing embodiments, and at least two of the first to fifth modifications may be combined with each other as appropriate.

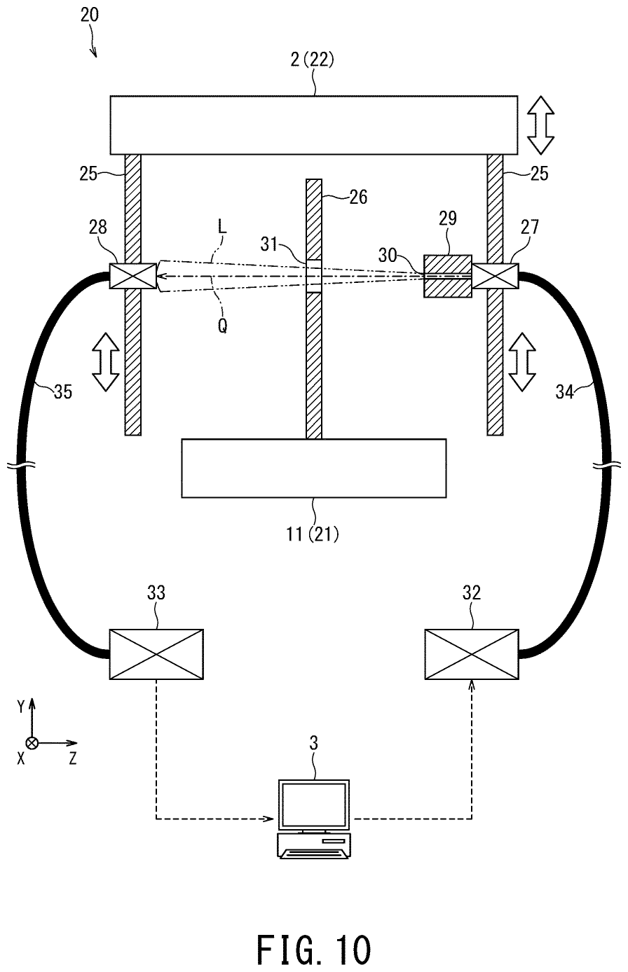

As shown in FIG. 10, the limit sensor apparatus 20 of the first modification includes: a single light-shielding plate 26 that serves as a light-shielding member fixed to the first jig 21; and two holding plates 25 fixed to the second jigs 22. The light-shielding plate 26 is fixed by the first jig 21 to the base 11 serving as the first member, which is the other member different from the multipole magnet 2 serving as the second member. An opening 31 through which the laser L passes is formed at the center of the light-shielding plate 26.

The light emitter 27 is fixed to one of the holding plates 25, and the light receiver 28 is fixed to the other of the holding plates 25. Accordingly, the light receiver 28 is fixed by the second jigs 22 to the same member (i.e., the multipole magnet 2 serving as the second member) to which the light emitter 27 is fixed.

In the first modification of the limit sensor apparatus 20, the same effects as those of the above-described embodiments can be achieved.

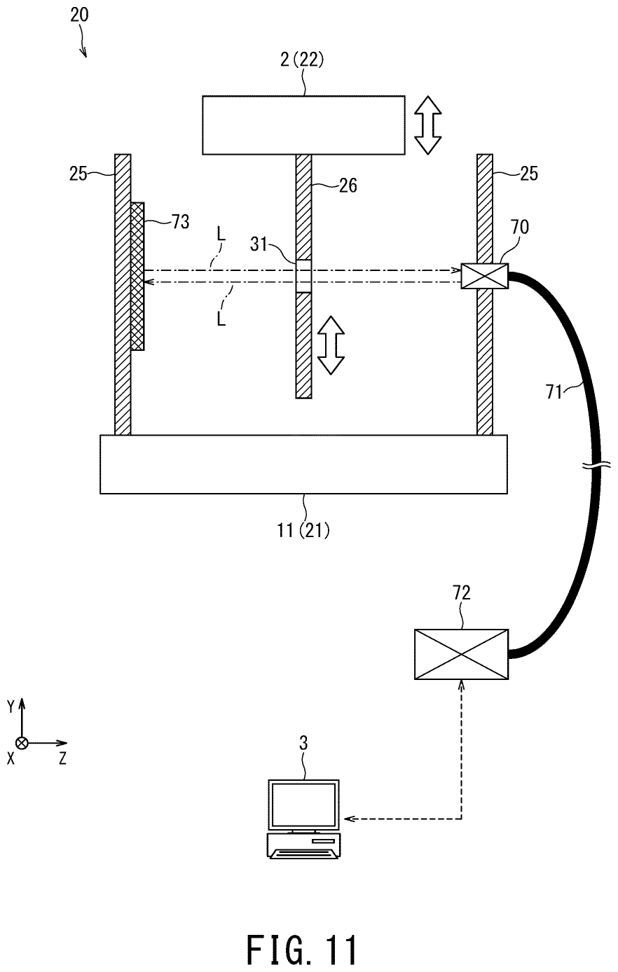

As shown in FIG. 11, the limit sensor apparatus 20 of the second modification is a reflective laser sensor that performs emission and reception of the laser L at a single location. The limit sensor apparatus 20 of the second modification includes a transceiver 70 that performs both emission and reception of the laser L. The transceiver 70 is connected to a laser oscillator/detector 72 via an optical fiber 71. The laser oscillator/detector 72 performs both emission and detection of the laser L and is connected to the position-adjustment computer 3.

Two holding plates 25 are fixed to the first jig 21. A single light-shielding plate 26 serving as the light-shielding member is fixed to the second jig 22. An opening 31 through which the laser L passes is formed in the center of the light-shielding plate 26.

The transceiver 70 is fixed to one of the holding plates 25. A reflector 73 configured to reflect the laser L is fixed to the other of the holding plates 25. The reflector 73 is, for example, a member such as a mirror configured to reflect the laser L. This reflector 73 is fixed by the first jig 21 to the base 11 serving as the first member, which is the same one member to which the transceiver 70 is fixed. The laser L emitted from the transceiver 70 is reflected by the reflector 73 and then received by the transceiver 70.

In the limit sensor apparatus 20 of the second modification, the same effects as those of the above-described embodiments can be achieved. Since the transceiver 70 both emits and receives the laser L, installation is facilitated, the number of components can be reduced, and thereby manufacturing cost can be reduced.

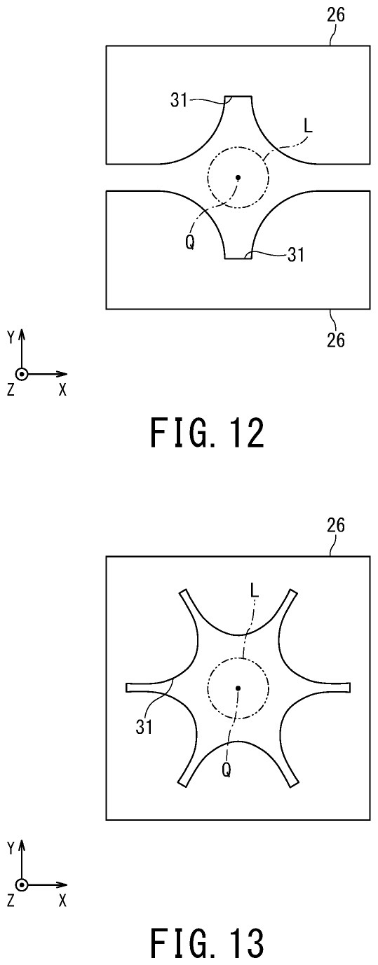

As shown in FIG. 12, the light-shielding member of the third modification is composed of two vertically divided light-shielding plates 26. Both the light-shielding plates 26 are notched in such a manner that the opening 31 of the lower edge of the upper light-shielding plate 26 and the opening 31 of the upper edge of the lower light-shielding plate 26 form a shape corresponding to the central opening of the multipole magnet 2. Four rounded edges (curved edges) corresponding to the four core projections 8 (see FIG. 2) are formed at the four corners of the opening 31.

In the light-shielding member of the third modification, the same effects as those of the above-described embodiments can be achieved. Since it is composed of two separate light-shielding plates 26, the shapes of the respective openings 31 are easy to fabricate. The light-shielding member may also be composed of three or more light-shielding plates 26 that are divided.

As shown in FIG. 13, the light-shielding plate 26 serving as the light-shielding member of the fourth modification is for a case where the multipole magnet 2 is a hexapole magnet. For example, six rounded (curved) edges corresponding to the six core projections 8 of the hexapole magnet are formed at the central opening 31 of the light-shielding plate 26.

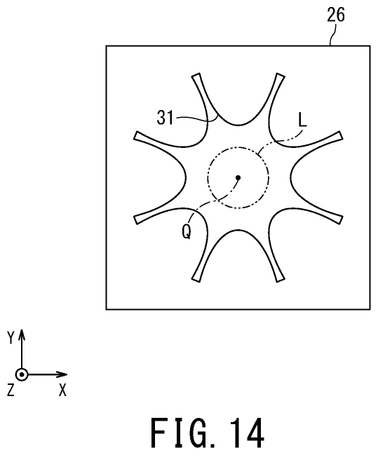

In the light-shielding member of the fourth modification, the same effects as those of the above-described embodiments can be achieved. Depending on the type of the multipole magnet 2, such as a dipole magnet and an octupole magnet as shown in FIG. 14 illustrating the fifth modification, the central opening 31 of the light-shielding plate 26 may have the same number of rounded (curved) edges as the number of the core projections 8.

The above-described position-adjustment computer 3 includes a control device, a storage device, an output device, an input device, and a communication interface. The control device includes a highly integrated processor such as a central processing unit (CPU), a graphics processing unit (GPU), a field programmable gate array (FPGA), and a dedicated chip. The storage device includes a read only memory (ROM), a random access memory (RAM), a hard disk drive (HDD), and/or a solid state drive (SSD), for example. The output device includes a display panel, a head-mounted display, a projector, and/or a printer, for example. The input device includes a mouse, a keyboard, and/or a touch panel, for example. The position-adjustment computer 3 can be achieved by a hardware configuration using a general computer.

The programs to be executed by the above-described position-adjustment computer 3 is pre-stored and provided in, for example, a ROM. Additionally or alternatively, the programs may be provided by being stored in a computer-readable and non-transitory storage medium in the form of an installable or executable file. The storage medium includes a CD-ROM, a CD-R, a memory card, a DVD, and/or a flexible disk (FD), for example.

The programs to be executed by the position-adjustment computer 3 may be stored in a computer connected to a network such as the Internet and be provided by being downloaded via the network. In other words, the programs may be provided from a cloud computing resource.

It may also be configured in such a manner that the programs are executed by a server on the cloud and only the processing result is provided via the cloud. The position-adjustment computer 3 may also be configured by: interconnecting separate modules, each independently implementing a respective function, via a network or a dedicated line; and combining these modules.

Although the multipole magnets 2 serving as the subjects of position adjustment by the multipole magnet adjustment system 1 are used in the particle beam irradiation system in the above-described embodiments, other configurations may be adopted. For example, the multipole magnets 2 may be used in a predetermined accelerator.

Although the limit detection system, i.e., the multipole magnet adjustment system 1, detects the limit positions of movement at the time of the position adjustment of each multipole magnet 2 in the above-described embodiments, other configurations may be adopted. For example, the limit detection system may detect the limit positions of movement of a predetermined member or device other than the multipole magnets 2. For example, the limit detection system may be applied to machine tools, construction equipment, manufacturing equipment, or moving devices.

Although a single light-shielding plate 26 is disposed between two holding plates 25 in the above-described embodiments, other configurations may be adopted. For example, two or more light-shielding plates 26 may be disposed between the two holding plates 25.

Although the plate-shaped light-shielding plate 26 serving as the light-shielding member is illustrated in the above-described embodiments, other configurations may be adopted. For example, the light-shielding member may have a block shape with an opening 31 formed at its center or may have a cylindrical or tubular shape.

According to the above-described embodiments, the screen 50 displays the schematic image 51 indicating the positional relationship between the multipole magnet 2 surrounding the vacuum duct 5 and the vacuum duct 5 through which the charged particle beam B passes. This configuration allows a user such as an operator to perform remote position adjustment of each multipole magnet 2 safely and easily while avoiding a collision between the multipole magnet 2 and the vacuum duct 5.

At least one light-shielding member formed with an opening 31, through which the laser L passes, is provided on the optical path of the laser L between the light emitter 27 and the light receiver 28. With this configuration, even adoption of a simple structure enables detection of positional deviation of the member to be subjected to position adjustment without adversely affecting the member.

While certain embodiments have been described, these embodiments have been presented by way of example only, and are not intended to limit the scope of the inventions. Indeed, the novel embodiments described herein may be embodied in a variety of other forms; furthermore, various omissions, substitutions, changes, and combinations in the form of the embodiments described herein may be made without departing from the spirit of the inventions. The accompanying claims and their equivalents are intended to cover such forms or modifications as would fall within the scope and spirit of the inventions.

Notwithstanding the foregoing, unless otherwise clearly indicated by the context, a singular expression is not intended to exclude a plural form. Conjunctive terms such as “and” and “or” are inclusive, unless otherwise clearly indicated by the context.

1. A multipole magnet adjustment system comprising:
an X-axis drive motor configured to move a multipole magnet in an X-axis direction that is orthogonal to a traveling direction of the charged particle beam, the multipole magnet being configured to control a charged particle beam;
a Y-axis drive motor configured to move the multipole magnet in a Y-axis direction that is orthogonal to both the traveling direction and the X-axis direction; and
a computer configured to
control the X-axis drive motor and the Y-axis drive motor,
display a schematic image on a screen, the schematic image indicating a positional relationship between a vacuum duct and the multipole magnet surrounding the vacuum duct, the vacuum duct being a duct through which the charged particle beam passes, and
move a displayed position of the multipole magnet on the screen in response to movement of the multipole magnet caused by driving of the X-axis drive motor and the Y-axis drive motor.

2. The multipole magnet adjustment system according to claim 1, wherein the computer is configured to display a numerical value together with the schematic image on the screen, the numerical value indicating an actual position of the multipole magnet.

3. The multipole magnet adjustment system according to claim 1, wherein the computer is configured to display setting values together with the schematic image on the screen, the setting values indicating respective driving amounts of the X-axis drive motor and the Y-axis drive motor.

4. The multipole magnet adjustment system according to claim 1, wherein the computer is configured to display a limit value together with the schematic image on the screen, the limit value indicating a limit position of a movement range of the multipole magnet.

5. The multipole magnet adjustment system according to claim 1, further comprising a limit sensor apparatus configured to detect the multipole magnet reaching a limit position during positioning of the multipole magnet with respect to the vacuum duct.

6. The multipole magnet adjustment system according to claim 1, further comprising:
a light emitter configured to emit a laser and fixed to one of two members that are the multipole magnet and a base for fixing the multipole magnet;
a light receiver configured to receive the laser and fixed to a same one of the two members as a member to which the light emitter is fixed; and
at least one light-shielding member fixed to another of the two members, disposed on an optical path of the laser from the light emitter to the light receiver, formed with an opening through which the laser passes,
wherein the computer is configured to:
acquire an amount of received light by the light receiver; and
detect a positional displacement between the multipole magnet and the base depending on a difference between (i) the amount of received light when the laser having passed through the opening reaches the light receiver and (ii) the amount of received light when the laser at least partially blocked by the light-shielding member reaches the light receiver.

7. The multipole magnet adjustment system according to claim 6, wherein the computer is configured to acquire a change amount indicating a magnitude of the positional displacement depending on the difference.

8. The multipole magnet adjustment system according to claim 6, further comprising:
a laser oscillator provided at a position different from a position of the light emitter, connected to the light emitter via an emitting optical fiber, and configured to emit the laser; and
a laser detector provided at a position different from a position of the light receiver, connected to the light receiver via a receiving optical fiber, and configured to detect the laser.

9. The multipole magnet adjustment system according to claim 6, wherein:
the opening is formed to have a shape corresponding to a relative movement range between the multipole magnet and the base; and
a limit position of the movement range is set by an edge of the opening.

10. A multipole magnet adjustment method using: (a) an X-axis drive motor configured to move a multipole magnet in an X-axis direction orthogonal to a traveling direction of the charged particle beam, the a multipole magnet being configured to control a charged particle beam; (b) a Y-axis drive motor configured to move the multipole magnet in a Y-axis direction orthogonal to both the traveling direction and the X-axis direction; and (c) a computer,
the multipole magnet adjustment method comprising steps of:
causing the computer to control the X-axis drive motor and the Y-axis drive motor;
causing the computer to display a schematic image on a screen, the schematic image indicating a positional relationship between a vacuum duct and the multipole magnet surrounding the vacuum duct, the vacuum duct being a duct through which the charged particle beam passes; and
causing the computer to move a displayed position of the multipole magnet on the screen in response to movement of the multipole magnet caused by driving of the X-axis drive motor and the Y-axis drive motor.

11. The multipole magnet adjustment system according to claim 2, wherein the computer is configured to display setting values together with the schematic image on the screen, the setting values indicating respective driving amounts of the X-axis drive motor and the Y-axis drive motor.

12. The multipole magnet adjustment system according to claim 2, wherein the computer is configured to display a limit value together with the schematic image on the screen, the limit value indicating a limit position of a movement range of the multipole magnet.

13. The multipole magnet adjustment system according to claim 2, further comprising a limit sensor apparatus configured to detect the multipole magnet reaching a limit position during positioning of the multipole magnet with respect to the vacuum duct.

14. The multipole magnet adjustment system according to claim 2, further comprising:
a light emitter configured to emit a laser and fixed to one of two members that are the multipole magnet and a base for fixing the multipole magnet;
a light receiver configured to receive the laser and fixed to a same one of the two members as a member to which the light emitter is fixed; and
at least one light-shielding member fixed to another of the two members, disposed on an optical path of the laser from the light emitter to the light receiver, formed with an opening through which the laser passes,
wherein the computer is configured to:
acquire an amount of received light by the light receiver; and
detect a positional displacement between the multipole magnet and the base depending on a difference between (i) the amount of received light when the laser having passed through the opening reaches the light receiver and (ii) the amount of received light when the laser at least partially blocked by the light-shielding member reaches the light receiver.
